(19) United States
(12) Patent Application Publication
(10) Pub. No.: US 2004/0093461 A1
(43) Pub. Date: May 13, 2004

(54) Self-refresh device and method

(76) Inventor: Tae Yun Kim, Chungcheongbuk-do (KR)

Correspondence Address: HELLER EHRMAN WHITE & MCAULIFFE LLP, 1666 K STREET,NW, SUITE 300, WASHINGTON, DC, 20006, US

(21) Appl. No.: 10/608,575

(22) Filed: Jun. 30, 2003

(30) Foreign Application Priority Data
Nov. 7, 2002 (KR) 2002-68749

(51) Int. Cl. G06F 12/00; G11C 7/00

(52) U.S. Cl. 711/106; 365/222

(57) ABSTRACT

The present invention generally relates to a self-refresh device and method, and more specifically, to a PASR (Partial Array Self-Refresh) device and method for selectively performing a refresh operation on a cell array requiring a refresh in a self-refresh mode. According to the present invention, a selective refresh operation is performed on a cell array requiring a refresh by setting the self-refresh information as an EMRS (Extended Mode Register Set) code and selectively activating a cell array in response to a bank selection address. Here, a refresh operation is not performed on a cell array which does not require a refresh in a self-refresh mode. Accordingly, the power consumption of a memory can be considerably reduced, and noise can be also decreased by reducing peak operation current.

### BACKGROUND OF THE INVENTION

1. Field of the Invention

The present invention generally relates to a self-refresh device and method thereof, and more specifically, to a technique which can reduce the power consumption during a self-refresh operation of a semiconductor memory device.

2. Description of the Prior Art

In a DRAM used as a main memory device of a computer system, a refresh is generally required to prevent data loss of a cell. Particularly, since portable apparatuses such as laptop computers or personal digital assistants (PDA) should have small power consumption in a stand-by state, it is important to reduce operation current for keeping data in the stand-by state.

In a DRAM used in the low-power portable apparatus, a self-refresh operation is generally performed to preserve data in the stand-by state. As a result, reducing operation current consumed in a self-refresh mode can result in decreasing the total power consumption in the DRAM.

However, in a conventional DRAM, a refresh operation is performed on all cell arrays without considering whether or not a data is stored in a cell array. As a result, unnecessary power is consumed because the refresh operation is performed even on a cell array where data is not stored.

In order to overcome the problem, a conventional DRAM device has an additional memory device for memorizing which cell array stores data, and a refresh operation is selectively performed only on a cell array where data is stored. However, according to the conventional DRAM device, the chip size of the semiconductor memory is increased due to the additional memory device.

### SUMMARY OF THE INVENTION

It is an object of the present invention to reduce power consumption of a memory by selectively performing a refresh operation on a cell array activated in response to a bank selection address.

There is provided a self-refresh device comprising: a partial array self-refresh decoder for decoding and latching an address preset as an extended mode register set code in response to a mode register set signal, and then selectively activating a plurality of control signals for performing a partial array self-refresh operation by combining corresponding addresses when a self-refresh signal is activated; and a row address strobe generator for controlling a row active signal for selectively activating at least one or more banks depending on states of the plurality of control signals when a refresh operation signal is activated, or selectively activating a certain array region selected in a single bank.

There is also provided a self-refresh method, where refresh modes are classified, into a plurality of modes including a HALF of BANK mode for refreshing a half of one bank and a QUARTER of BANK mode for refreshing a quarter of one bank, depending on extended mode register set codes, the method comprising the step of performing a partial self-refresh operation to an array region where data is stored, by performing one of the plurality of self-refresh modes depending on the extended mode register set codes.

### BRIEF DESCRIPTION OF THE DRAWINGS

FIG. 1 is a diagram illustrating an EMRS code applied to the present invention.

FIG. 2 is a timing diagram illustrating a self-refresh entry and exit mode according to the present invention.

FIG. 3 is a structural diagram illustrating a self-refresh device according to the present invention.

FIG. 4 is a timing diagram illustrating the operation of the self-refresh device according to the present invention.

FIG. 5 is a detailed structural diagram illustrating a PASR decoder(40) of FIG. 3.

FIG. 6 is a detailed schematic diagram illustrating an EMRS decoder(41) of FIG. 5.

FIG. 7 is a detailed schematic diagram illustrating address latches(42,43,44) of FIG. 5.

FIG. 8 is a detailed schematic diagram illustrating a PASR controller(45) of FIG. 5.

FIG. 9 is a detailed schematic diagram illustrating RAS generators(50,60,70,80) of FIG. 3.

FIG. 10 is a timing diagram illustrating the operation of control signals for controlling the RAS generators of FIG. 9.

### DETAILED DESCRIPTION OF THE PREFERRED EMBODIMENTS

The present will be described in more detail with reference to the accompanied drawings.

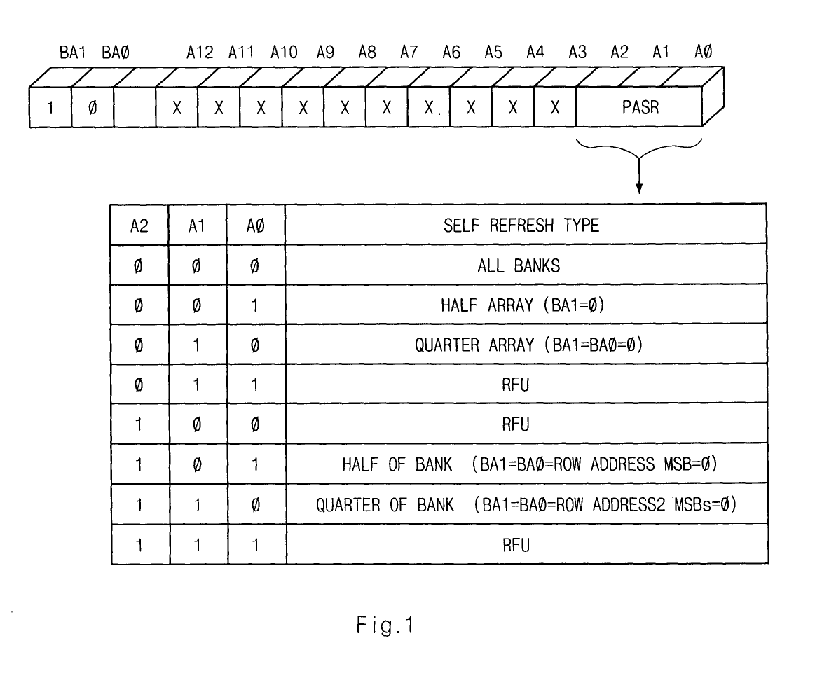

FIG. 1 is a diagram illustrating an extended mode register set (hereinafter, referred to as ‘EMRS’) code applied to the present invention.

According to the present invention, a selective refresh operation is performed only on a cell array requiring a refresh. This self-refresh method is called a partial array self refresh (hereinafter, referred to as ‘PASR’) operation.

Referring to FIG. 1, address bits A0˜A2 of EMRS codes are used for setting a PASR operation. When an EMRS code is externally inputted, a corresponding self-refresh operation is performed according to the EMRS code.

When the address bits A0˜A2 become 0, a self-refresh operation is performed on the whole cell by selecting “ALL BANKS” like in a normal mode. When the address bit A0 becomes 1, a self-refresh operation is performed on a half of the whole cell array by selecting a “HALF ARRAY”. For example, in a DRAM having a four bank structure, a self-refresh operation is performed on two banks. Here, a bank selection address bit BA1 becomes 0.

When only the address bit A1 becomes 1, a self-refresh operation is performed on a quarter of the whole cell array by selecting a “QUARTER ARRAY”. For example, in a DRAM having a four bank structure, a self-refresh operation is performed on one bank. Here, both of the bank selection address bits BA0 and BA1 become both 0.

When only the address bit A1 becomes 0, a self-refresh operation is performed on a half cell array of one bank by selecting a “HALF OF BANK”. In other words, in a DRAM having a four bank structure, a self-refresh operation is performed on a half cell array of a bank. Here, one of the bank address bits BA0 and BA1, which are most significant bits of a row address, becomes 0.

When only the address bit A0 becomes 0, a self-refresh operation is performed on a quarter cell array of one bank by selecting a “QUARTER OF BANK”. In other words, in a DRAM having a four bank structure, a self-refresh operation is performed on a quarter cell array of a bank. Here, both of the bank address bits BA0 and BA1, which are the most significant bits of the row address, become 0.

Additionally, the case when only the address bit A2 is 0, the case when the only the address bit A2 is 1, and the case when all address bits A0˜A2 are 1 are reserved for future use(RFU).

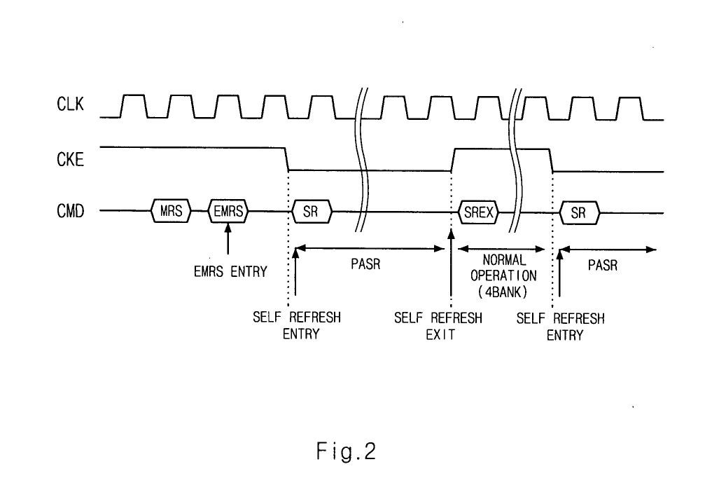

FIG. 2 is a timing diagram illustrating entry and exit operation of the self-refresh in a PASR operation according to the present invention.

First, a PASR type is preset to the EMRS code. When a clock enable signal CKE is disabled to a low level, a self-refresh command SR is inputted, and a partial array self refresh PASR operation is performed. Here, a selective self-refresh operation is performed according to the PASR type preset to the EMRS code.

If a self-refresh exit command SREX is applied after the clock enable signal CKE is enabled to a high level, the self-refresh operation is finished, and a normal operation is performed. In the normal operation mode, a self-refresh operation is performed on all cell arrays.

If the self-refresh command SR is applied again there after, the PASR operation is performed according to the preset EMRS code.

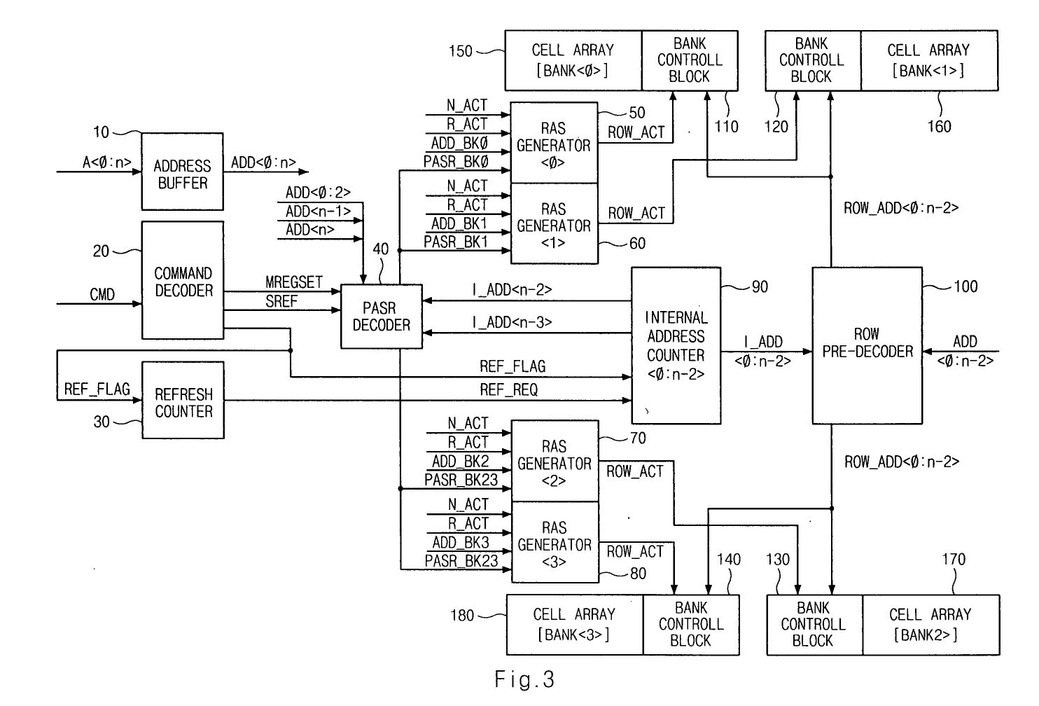

FIG. 3 is a structural diagram illustrating the self-refresh device according to the present invention.

The self-refresh device of the present invention comprises an address buffer 10, a command decoder 20, a refresh counter 30, a PASR decoder 40, RAS (Row Address Strobe) generators 50˜80, an internal address counter 90, a row pre-decoder 100, bank control blocks 110˜140 and banks 150˜180 including a plurality of a cell array.

Here, the address buffer 10 buffers an externally applied address bits ADD<0:n>, and then outputs a buffered address bits ADD<0:n>. The command decoder 20 decodes an externally applied command signal CMD, and then outputs a mode register set signal MREGSET, a self-refresh signal SREF and a refresh flag signal REF_FLAG.

The refresh counter 30 performs a counting operation corresponding to a refresh cycle when the refresh flag signal REF_FLAG representing a self-refresh operation is activated. The refresh counter 30 generates a refresh request signal REF_REQ according to a refresh rate.

The PASR decoder 40 decodes the mode register set signal MREGSET, the self-refresh signal SREF, an bank selection address bits ADD<n> and ADD<n−1>, an address bits ADD<0:2> and internal address bits I_ADD<n−2> and I_ADD<n−3>, and outputs control signals PASR_BK0, PASR_BK1 and PASR_BK23 for performing a PASR operation according to the preset code.

The RAS (Row address Strobe) generator 50 outputs a row active signal ROW_ACT into the bank control block 110 in response to a normal operation signal N_ACT, a refresh operation signal R_ACT, a bank selection address ADD_BK0 and a control signal PASR_BK0. The RAS generator 60 outputs a row active signal ROW_ACT into the bank control block 120 in response to a normal operation signal N_ACT, a refresh operation signal R_ACT, a bank selection address ADD_BK1 and a control signal PASR_BK1.

The RAS generator 70 outputs a row active signal ROW_ACT into the bank control block 130 in response to a normal operation signal N_ACT, a refresh operation signal R_ACT, a bank selection address ADD_BK2 and a control signal PASR_BK23. The RAS generator 80 outputs a row active signal ROW_ACT into the bank control block 140 in response to a normal operation signal N_ACT, a refresh operation signal R_ACT, a bank selection address ADD_BK3 and a control signal PASR_BK23.

The internal address counter 90 counts internal addresses in response to the refresh flag signal REF_FLAG and the refresh request signal REF_REQ. And the internal address counter 90 outputs internal address bits I_ADD<n−2> and I_ADD<n−3> into the PASR decoder 40 and an internal address bits I_ADD<0:n−2> into the row pre-decoder 100.

The row pre-decoder 100 pre-decodes an externally inputted external address bits ADD<0:n−2> and an internal address bits I_ADD<0:n−2>. In a normal mode, the row pre-decoder 100 outputs the external address bits ADD<0:n−2> as a row address bits ROW_ADD<0:n−2> into bank control block 110˜140. In a refresh mode, the row pre-decoder 100 outputs the internal address bits I_ADD<0:n−2> as a row address bits ROW_ADD<0:n−2> into bank control blocks 110˜140.

The bank control blocks 110˜140 control banks 150˜180 each of which comprises cell array unit. Here, the address bits ADD<0:n> is a row address corresponding to a memory depth. A most significant bit of a row address bits ADD<0:n> is used as a bank selection address.

If there are four banks, two bank selection address bits are required. Here, address bits ADD<n> and ADD<n−1> are the bank selection address bits, and address bits ADD<0>˜ADD<n−2> are address bits for selecting an array and a wordline of each bank.

Hereinafter, the operation process of the self-refresh device according to the present invention is described below.

First, if the command signal CMD representing the EMRS is externally inputted, the command decoder 20 activates the mode register set signal MREGSET. The PASR decoder 40 sets the PASR operation according to the EMRS code by decoding the mode register set signal MREGSET, the address bits ADD<0:2> and the bank selection address bits ADD<n> and ADD<n−1>, and latches the set information. The latched information in the PASR decoder 40 is maintained before a different EMRS code is inputted.

Then, the self-refresh command SR is externally inputted as shown in FIG. 2., the self-refresh flag signal REF_FLAG and the self-refresh signal SREF representing a self-refresh state are generated at the command decoder 20. The PASR decoder 40 selectively outputs control signals PASR_BK0, PASR_BK1 and PASR_BK23 into RAS generators 50˜80 in response to the latched PASR information.

Here, the PASR decoder 40 activates the control signals PASR_BK0, PASR_BK1 and PASR_BK23, thereby maintaining the RAS generators 50˜80 at an activatable state.

If one of the RAS generators 50˜80 is activated according to the states of the bank selection address bits ADD<n> and ADD<n−1>, one bank of the cell array unit banks 150˜180 is selected in response to the row active signal ROW_ACT. The row pre-decoder 100 outputs an external address bits ADD<0:n−2> of a corresponding bank as a row address bits ROW_ADD<n−2>. As a result, a corresponding wordline of the cell array is activated.

When the EMRS code is “ALL BANKS”, the control signals PASR_BK0, PASR-BK1 and PASR_BK23 are all activated. As a result, all the RAS generators 50˜80 are maintained active. Then, the row pre-decoder 100 outputs an internal address bits I_ADD<0:n−2> generated at the internal address counter 90 as a row address bits ROW_ADD<0:n−2>. As a result, a corresponding wordline is activated in all the banks 150˜180.

When the EMRS code is “HALF ARRAY”, the control signals PASR_BK0 and PASR_BK1 are activated, and the control signal PASR_BK23 is inactivated. As a result, the RAS generators 50 and 60 are activated, and the banks 150 and 160 are activated in response to the row active signal ROW_ACT.

Then, the row pre-decoder 100 outputs an internal address bits I_ADD<0:n−2> generated from the internal address counter 90 as a row address bits ROW_ADD<0:n−2>. As a result, a wordline corresponding to the row address bits ROW_ADD<0:n−2> is activated in the banks 150 and 160. Here, the RAS generators 70 and 80 are inactivated in response to the control signal PASR_BK23, and the banks 170 and 180 do not operate.

When the EMRS code is “QUARTER ARRAY”, the PASR decoder 40 activates the control signal PASR_BK0, and inactivates the control signals PASR_BK1 and PASR_BK23. As a result, the RAS generator 50 is maintained at an active.

Here, the row pre-decoder 100 outputs an internal address bits I_ADD<0:n−2> generated from the internal address counter 90 as a row address bits ROW_ADD<0:n−2>. As a result, a wordline corresponding to the row address bits ROW_ADD<n−2> is activated in the bank 150. The RAS generators 60˜80 are inactivated in reponse to the control signals PASR_BK1 and PASR_BK23, and the banks 160˜180 do not operate.

When the EMRS code is “HALF of BANK”, the control signal PASR_BK0 is activated, and the control signals PASR_BK1 and PASR_BK23 are inactivated. Here, the PASR decoder 40 inactivates the control signal PASR_BK0 when the internal address bits I_ADD<n−2> generated from the address counter 90 has a high phase.

The PASR decoder 40 inactivates the active control signal PASR_BK0 when a most significant bit address in a bank has a high phase. As a result, the bank 150 is not operated. Thus, a self-refresh operation is performed on a half cell array in the bank 150 during a predetermined refresh period.

When the EMRS code is “QUARTER OF BANK”, the control signal PASR_BK0 of the PASR decoder 40 is activated, and the control signals PASR_BK1 and PASR_BK23 are inactivated.

Here, the PASR decoder 40 inactivates the control signal PASR_BK0 when the internal address bit I_ADD<n−2> generated from the internal address counter 90 has a high phase or an internal address bit I_ADD<n−3> has a high phase.

The PASR decoder 40 inactivates the active control signal PASR_BK0 when at least one of two most significant bits of the address in a bank is high. As a result, the bank 150 does not operate. Thus, a self-refresh operation is performed on a quarter cell array of the bank 150 during a predetermined refresh period.

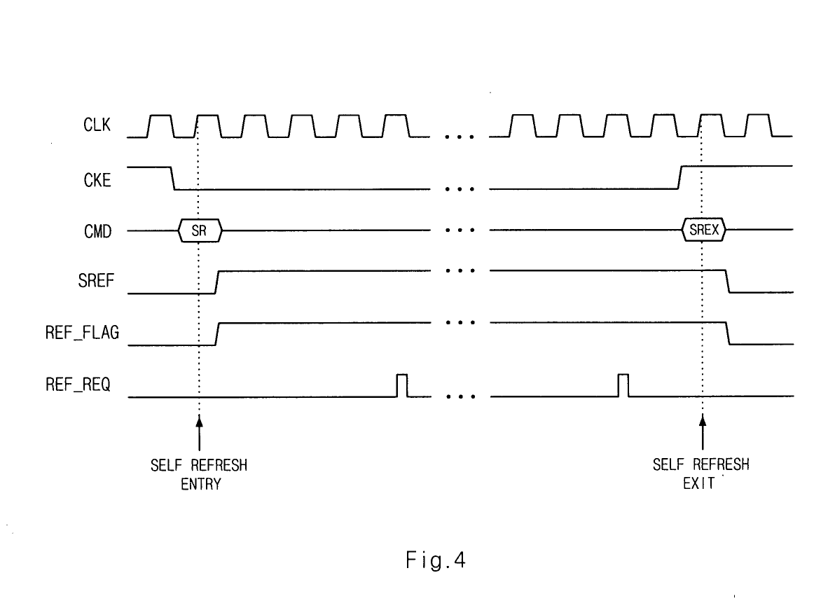

FIG. 4 is a timing diagram illustrating the operation of the self-refresh device according to input of external commands.

First, the self-refresh signal SREF is activated by the self-refresh command SR, and inactivated by the self-refresh exit command SREX. Here, the refresh flag signal REF_FLAG is maintained active during a self-refresh period. In a refresh operation, the refresh request signal REF_REQ generates a pulse signal as many as a predetermined number of cycles during a refresh period determined by the internal refresh counter 30.

For example, the self-refresh device refreshes 8 K times for 64 msec, the refresh request signal REF_REQ generates 8 K pulse signals for 64 msec, and a time interval between pulses becomes 8 usec.

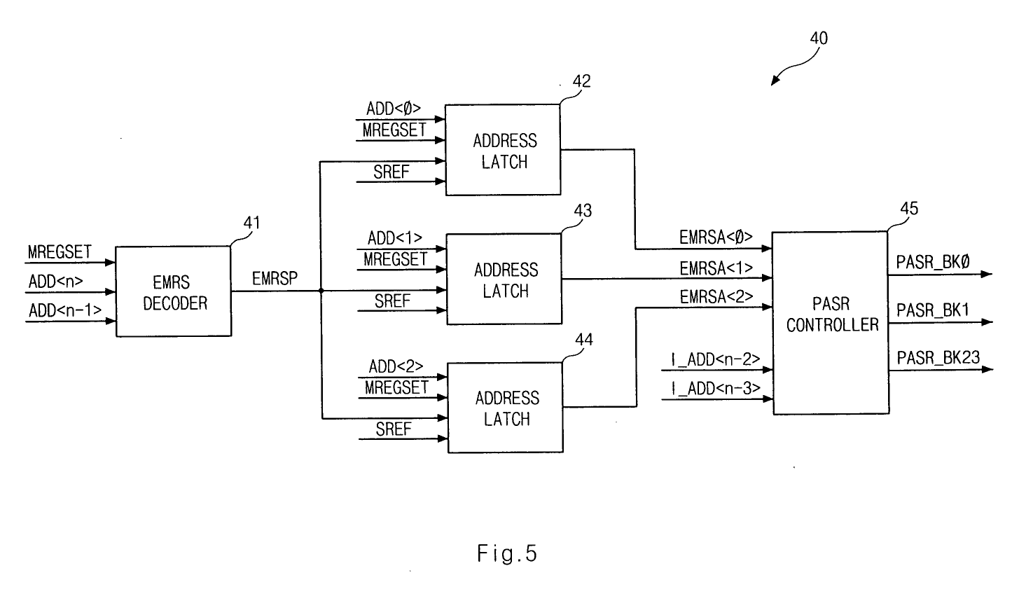

FIG. 5 is a detailed structural diagram illustrating the PASR decoder 40 of FIG. 3.

The PASR decoder 40 comprises an EMRS decoder 41, address latches 42˜44, and a PASR controller 45.

Here, the EMRS decoder 41 outputs an register set control signal EMRSP by decoding the mode register signal MREGSET, and the bank selection address bits ADD<n> and ADD<n−1> applied from the command decoder 20.

The address latches 42˜44 store address bits ADD<0:2> representing PASR codes when an EMRS command is inputted. The address latch 42 outputs a register set address bit EMRSA<0> by latching an address bit ADD<0> in response to the mode register set signal MREGSET, the register set control signal EMRSP and the self-refresh signal SREF.

The address latch 43 outputs a register set address bit EMRSA<1> by latching an address bit ADD<1> in response to the mode register set signal MREGSET, the register set control signal EMRSP and the self-refresh signal SREF.

The address latch 44 outputs a register set address bit EMRSA<2> by latching an address bit ADD<2> in response to the mode register set signal MREGSET, the register set control signal EMRSP and the self-refresh signal SREF.

The PASR controller 45 enables a selective self-refresh operation on a cell array. The PASR controller 45 selectively activates the control signals PASR_BK0, PASR_BK1 and PASR_BK23 by logically operating a register set address bits EMRSA<0:2> and internal address bits I_ADD<n−2> and I_ADD<n−3>.

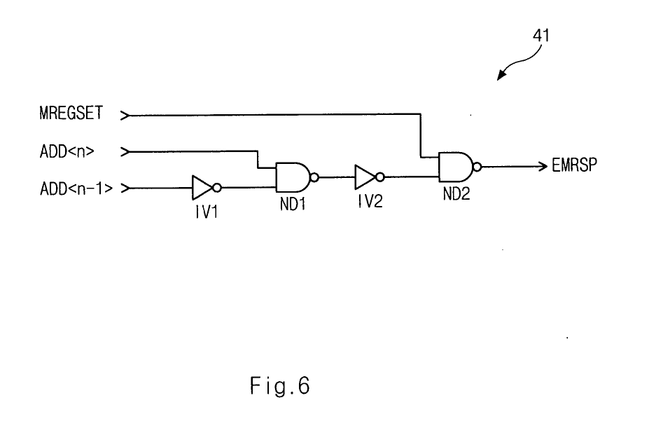

FIG. 6 is a detailed schematic diagram illustrating the EMRS decoder 41 of FIG. 5.

The EMRS decoder 41 comprises inverters IV1 and IV2, and NAND gates ND1 and ND2.

The inverter IV1 inverts a bank selection address bit ADD<n−1>. The NAND gate ND1 NANDs the bank selection address bit ADD<n−1> and an output signal of the inverter IV1. The inverter IV2 inverts an output signal of the NAND gate ND1. The NAND gate ND2 outputs the register set control signal EMRSP by NANDing the mode register set signal MREGSET and an output signal of the inverter IV2.

The operation process of the EMRS decoder 41 is described below.

If an EMRS command is externally inputted to perform a PASR operation, the command decoder 20 activates the mode register set signal MREGSET. The EMRS decoder 41 checks if the bank selection address bit ADD<n> of the address bits ADD<0:n> is high, and the bank selection address bit ADD<n−1> is low.

Thereafter, when the levels of the bank selection address bits ADD<n> and ADD<n−1> correspond to the EMRS codes of FIG. 1, the register set control signal EMRSP is activated.

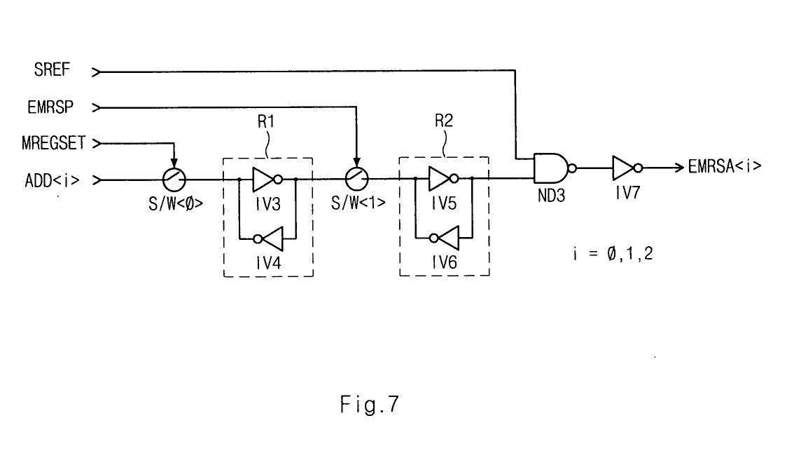

FIG. 7 is a detailed schematic diagram illustrating each of the EMRS address latches 42˜44 of FIG. 5.

Each of the EMRS address latches 42˜44 comprises switches S/W<0> and S/W<1>, latches R1 and R2, a NAND gate ND3 and an inverter IV7.

Here, the switch S/W<0> selectively outputs an address bit ADD<i> (here, i=0, 1, 2) according to the state of the mode register set signal MREGSET. The latch R1, which includes inverters IV3 and IV4, latches an output signal of the switch S/W<0>.

The switch S/W<1> selectively outputs an output signal of the latch R1 according to the state of the register set control signal EMRSP. The latch R2, which includes inverters IV5 and IV6, latches an output signal the switch S/W<1>.

The NAND gate ND3 NANDs the self-refresh signal SREF and an output signal of the latch R2. The inverter IV7 outputs a register set address bit EMRSA<i> (here, i=0, 1, 2) by inverting an output signal of the NAND gate ND3.

Each of the address latches 42˜44 latch an address bit ADD<i> inputted with the EMRS command. The switch S/W<0> is controlled by the mode register set signal MREGSET, and then the latch R1 latches and outputs the address bits ADD<i>. The switch S/W<1> is controlled by the register set control signal EMRSP, and then the latch R2 latches and outputs an output signal of the latch R1.

Thereafter, the register set address bit EMRSA<i> is activated according to input of the self-refresh signal SREF. When the self-refresh signal SREF is inactivated while the EMRS codes are latched, the register set address bit EMRSA<i> is maintained at a low level.

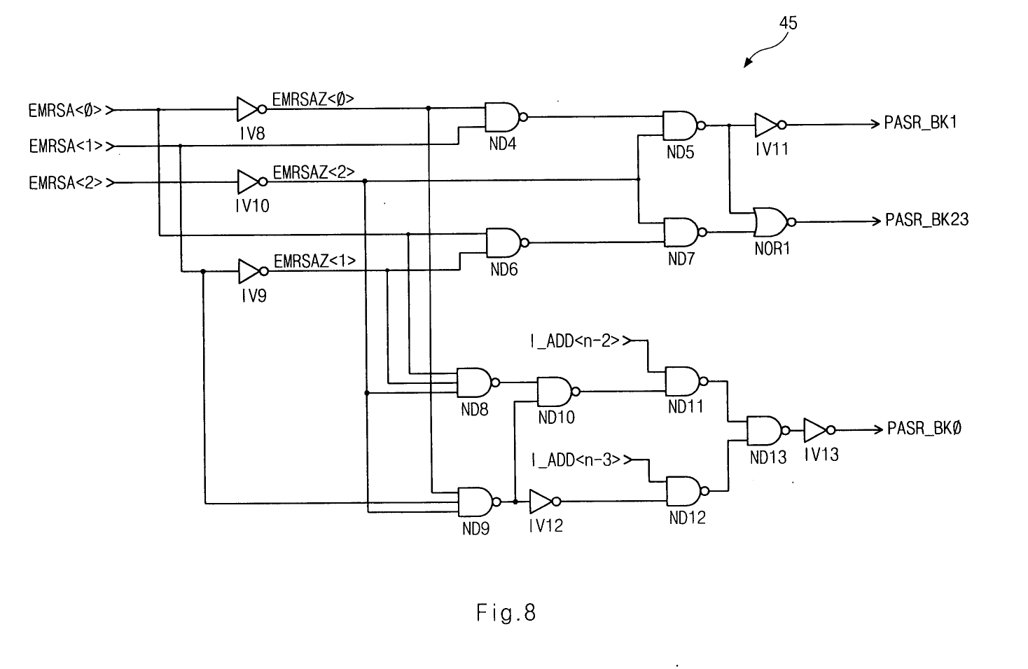

FIG. 8 is a detailed schematic diagram illustrating the PASR controller 45 of FIG. 5.

The PASR controller 45 comprises inverters IV8˜IV13, NAND gates ND4˜ND13, and a NOR gate NOR1.

The inverter IV8 outputs a register set address bit EMRSAZ<0> by inverting the register set address bit EMRSA<0>. The inverter IV9 outputs a register set address bit EMRSAZ<1> by inverting the register set address bit EMRSA<1>. The inverter IV10 outputs a register set addressbit EMRSAZ<2> by inverting the register set address bit EMRSA<2>.

The NAND gate ND4 NANDs the register set address bit EMRSAZ<0> and the register set address bit EMRSA<1>. The NAND gate ND5 NANDs an output signal of the NAND gate ND4 and the register set address bit EMRSAZ<2>. The inverter IV11 output the control signal PASR_BK1 by inverting an output signal of the NAND gate ND5.

The NAND gate ND6 NANDs the register set address bit EMRSA<0> and the register set address bit EMRSAZ<1>. The NAND gate ND7 NANDs the register set address bit EMRSAZ<2> and an output signal of the NAND gate ND6. The NOR gate NOR1 outputs the control signal PASR_BK23 by NORing an output signal of the NAND gate ND5 and an output signal of the NAND gate ND7.

The NAND gate ND8 NANDs the register set address bits EMRSA<0>, EMRSAZ<1> and EMRSAZ<2>. The NAND gate ND9 NANDs the register set address bits EMRSAZ<0>, EMRSA<1> and EMRSAZ<2>. The NAND gate ND10 NANDs output signals of the NAND gates ND8 and ND9. The inverter IV12 inverts an output signal of the NAND gate ND9.

The NAND gate ND11 NANDs the internal address bit I_ADD<n−2> and an outuput signal of the NAND gate ND10. The NAND gate ND12 NANDs the internal address bit I_ADD<n3>and an output signal of the inverter IV12. The NAND gate ND13 NANDs output signals of the NAND gates ND11 and ND12. The inverter IV13 outputs the control signal PASR_BK0 by inverting an output signal of the NAND gate ND13.

The operation process of the PASR controller 45 is described below.

In a normal mode, since the self-refresh signal SREF is at an inactive state, the register set address bits EMRSA<0:2> becomes low. As a result, all the control signals PASR_BK0, PASR_BK1 and PASR_BK23 become high.

In a self-refresh mode, the register set address bits EMRSA<0:2> represents the level of the address bits ADD<0:2> inputted together when the EMRS command is inputted. As a result, the control signals have the following level variations according to address bits ADD<0:2> when the EMRS command is inputted.

When an EMRS code is “ALL BANKS”, all the control signals PASR_BK0, PASR_BK1 and PASR_BK23 become high. When an EMRS code is “HALF ARRAY”, the control signals PASR_BK0 and PASR_BK1 become high, and the control signal PASR_BK23 becomes low.

When an EMRS code is “QUARTER ARRAY”, the control signal PASR_BK0 becomes high, and the control signals PASRBK1 and PASR_BK23 becomes low. When an EMRS code is “HALF OF BANK”, the control signal PASR_BK0 becomes high, and the control signals PASR_BK1 and PASR_BK23 become low. When an EMRS code is “QUARTER OF BANK”, the control signal PASR_BK0 becomes high, and the control signals PASR_BK1 and PASR_BK23 become low.

The control signals PASR_BK0, PASR_BK1 and PASR_BK23 are selectively outputted to activate the RAS generators 50˜80 according to preset address codes.

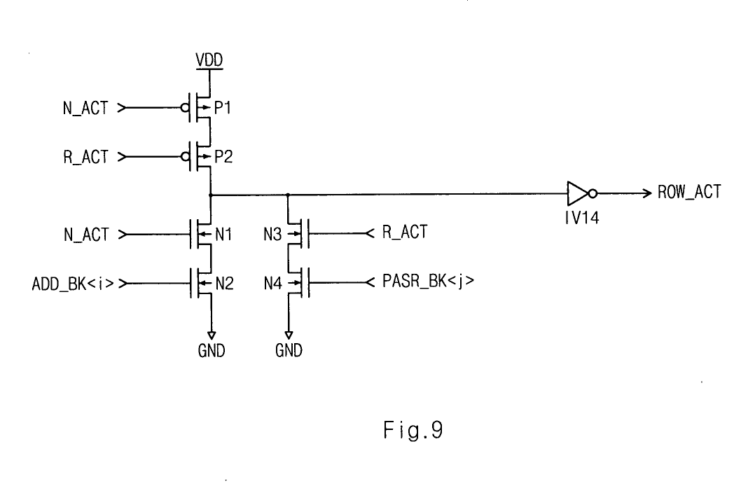

FIG. 9 is a detailed schematic diagram illustrating each of the RAS generators 50˜80 of FIG. 3.

Each of the RAS generators 50˜80 comprises PMOS transistors P1 and P2 and NMOS transistors N1 and N2 connected in series between a power source VDD terminal and a ground voltage GND terminal, and NMOS transistors N3 and N4 connected in series between the drain of the NMOS transistor N1 and the ground GND terminal.

The PMOS transistors P1 and P2 as a first switching means are selectively turned on in response to the normal operation signal N_ACT and the refresh operation signal R_ACT. The NMOS transistors N1 and N2 as a second switching means are turned on depending on the bank selection address bit ADD_BK<i> and the normal operation signal N_ACT, thereby activating the row active signal ROW_ACT. The NMOS transistors N3 and N4 as a third switching means are turned on depending on a control signal PASR_BK<j> (here, j=0, 1, 23) and the refresh operation signal R_ACT, thereby activating the row active signal ROW_ACT.

The PMOS transistor P1 has a gate to receive the normal operation signal N_ACT. The PMOS transistor P2 has a gate to receive the refresh operation signal R_ACT. The NMOS transistor N1 has a gate to receive the normal operation signal N_ACT. The NMOS transistor N2 has a gate to receive the bank selection address bit ADD_BK<i>.

Here, the NMOS transistor N3 has gate to receive the refresh operation signal R_ACT, and the NMOS transistor N4 has a gate to receive the control signal PASR_BK<j>.

The inverter IV14 outputs the row active signal ROW_ACT to activate a corresponding bank by inverting an output signal of the common drain of the NMOS transistors N1 and N3.

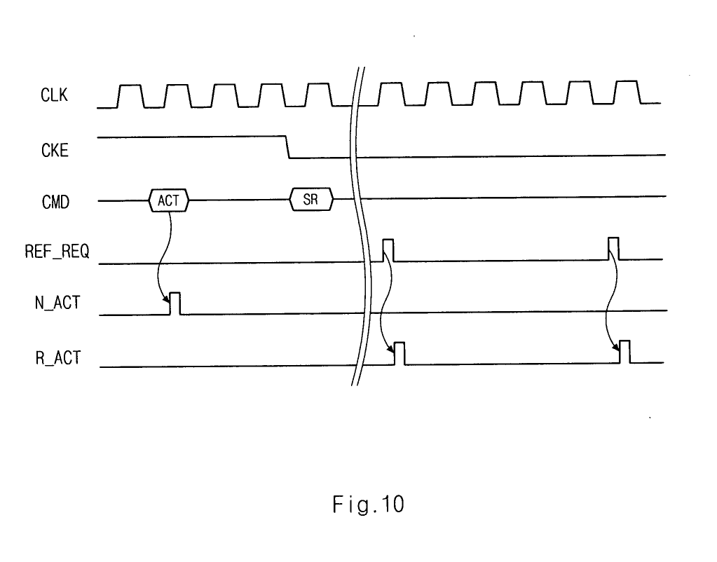

FIG. 10 is a timing diagram illustrating the operation of the normal operation signal N_ACT and the refresh operation signal R_ACT.

When an active command ACT is externally inputted in the normal mode, the normal operation signal N_ACT is activated. When the self-refresh command SR is inputted in the self-refresh mode, the refresh operation signal R_ACT is activated by activating the refresh request signal REF_REQ in the internal refresh counter 30.

As a result, since the normal operation signal N_ACT is activated in the normal active operation, the PMOS transistor P1 is turned off, and the NMOS transistor N1 is turned on. If the bank selection address bit ADD_BK<i> is at an active state, the row active signal ROW_ACT is activated. If the bank selection address bit ADD_BK<i> is inactive , the row active signal ROW_ACT is inactivated. Here, i=0, 1, 2, 3 correspond to each of the bank<0>, bank<1>, bank<2> and bank<3>. As a result, a bank having the activated row active signal ROW_ACT can be activated.

If the refresh operation signal R_ACT is activated in the self-refresh mode, the PMOS transistor P2 is turned off, and the NMOS transistor N3 is turned on. Here, the row active signal ROW_ACT is activated if the control signal PASR_BK<j> having the PASR information is active. And the row active signal ROW_ACT is inactivated if the control signal PASR_BK<j> is inactive. As a result, a bank having the activated row active signal ROW_ACT can be activated.

As discussed earlier, according to the present invention, a self-refresh operation is restrictively performed on an selected address regions in one or more banks, thereby considerably reducing the power consumption of a memory, and decreasing peak operation current to reduce noise.

What is claimed is:

1. A self-refresh device, comprising:
a partial array self-refresh decoder for decoding and latching an address preset as an extended mode register set code in response to a mode register set signal, and then selectively activating a plurality of control signals for performing a partial array self-refresh operation by combining corresponding addresses when a self-refresh signal is activated; and
a row address strobe generator for controlling a row active signal for selectively activating at least one or more banks depending on states of the plurality of control signals when a refresh operation signal is activated, or selectively activating a certain array region selected in a single bank.

2. The device according to claim 1, further comprising:
a command decoder for outputting the mode register set signal, the self-refresh signal and a refresh flag signal by decoding an externally inputted refresh command;
a refresh counter for outputting a refresh request signal by performing a counting operation corresponding to a refresh cycle in response to the refresh flag signal;
an internal address counter for counting and generating an internal address in response to the refresh flag signal and the refresh request signal; and
a row pre-decoder for outputting an external address as a row address in a normal mode, and outputting the internal address as the row address in a refresh mode.

3. The device according to claim 1, wherein the extended mode register set sets up a code for performing a self-refresh operation on a cell array corresponding to a half of one bank when a partial array self-refresh operation is in a half of bank mode, and for performing a self-refresh operation on a cell array corresponding to a quarter of one bank when a partial array self-refresh operation is in a quarter of bank mode.

4. The device according to claim 3, wherein when the partial array self-refresh operation is in a HALF of BANK mode, the partial array self-refresh decoder activates control signals corresponding to a quarter of the plurality of control signals until a most significant bit of address in the bank becomes high.

5. The device according to claim 3, wherein when the partial array self-refresh operation is in a quarter of bank mode, the partial array self-refresh decoder activates control signals corresponding to a quarter of the plurality of control signals until at least one of two most significant bits of address in the bank becomes high.

6. The device according to claim 1, wherein the partial array self-refresh decoder comprises:
an extended mode register set decoder for outputting a register set control signal by decoding a bank selection address in response to the mode register set signal;
a plurality of address latches each of which for outputting register set address bit by latching a address, in response to the register set control signal and the self-refresh signal when the mode register set signal is applied; and
a partial array self-refresh controller for selectively activating the plurality of control signals by decoding the plurality of register set addresses depending on input of the internal address.

7. The device according to claim 6, wherein the extended mode register set decoder activates the register set control signal at the activation of the mode register set signal when a most significant bit address of the bank selection address is high, and a second most significant bit of the bank selection address is low.

8. The device according to claim 7, wherein the extended mode register set decoder comprises:
a first inverter for inverting the second most significant bit of the bank selection address;
a first NAND gate for NANDing the most significant bit of the bank selection address and an output signal of the first inverter;
a second inverter for inverting an output signal of the first NAND gate; and
a second NAND gate for outputting the register set control signal by NANDing the mode register set signal and an output signal of the second inverter.

9. The device according to claim 6, wherein on of the plurality of address latches comprises:
a first switch for selectively outputting one of the plurality of addresses in response to the mode register set signal;
a first latch for latching an output signal of the first switch;
a second switch for selectively outputting an output signal of the first latch in response to the register set control signal;
a second latch for latching an output signal of the second switch; and
a first logic unit for outputting an output signal of the second latch as one of the plurality of register set addresses in activation of the self-refresh signal.

10. The device according to claim 9, wherein the first latch and the second latch, respectively, comprise a third inverter and a fourth inverter where each output signal is feedback as an input signal.

11. The device according to claim 9, wherein the first logic unit comprises:
a third NAND gate for NANDing the self-refresh signal and an output signal of the second latch; and
a seventh inverter for inverting an output signal of the third NAND gate.

12. The device according to claim 6, wherein the partial array self-refresh controller outputs first, second and third control signals obtained by decoding the plurality of register set addresses and the plurality of inverted register set addresses, and
the first control signal is selectively outputted in response to the internal address.

13. The device according to claim 12, wherein the first control signal is outputted when a most and a second most significant bits of the internal address are both high, or when one of the most and the second most significant bits of the bank selection address is high.

14. The device according to claim 1, wherein the row address strobe generator controls the row active signal depending on a bank selection address and a normal operation signal activated in a normal mode, and controls the row active signal depending on the plurality of control signals and the refresh operation signal activated in a refresh mode.

15. The device according to claim 14, wherein the row address strobe generator comprises:
a first switching means for being selectively turned on in response to the normal operation signal and the refresh operation signal;
a second switching means for being turned on depending on activation of the bank selection address when the normal operation signal is activated, and then activating the row active signal; and
a third switching means for being turned on depending on activation of the plurality of control signals when the refresh operation signal corresponding to a refresh request signal is activated, and then activating the row active signal.

16. The device according to claim 15, wherein the first switching means comprises a first PMOS transistor and a second PMOS transistor connected in series between a power source terminal and the second switching means, the first PMOS transistor and the second PMOS transistor having each gate to receive the normal operation signal and the refresh operation signal, respectively.

17. The device according to claim 15, wherein the second switching means comprises a first NMOS transistor and a second NMOS transistor connected between the first switching means and a ground terminal, the first NMOS transistor and the second NMOS transistor having gates to receive the normal operation signal and the bank selection address, respectively.

18. The device according to claim 15, wherein the third switching means comprises a third NMOS transistor and a fourth NMOS transistor connected between the first switching means and a ground terminal, the third NMOS transistor and the fourth NMOS transistor having gates to receive the refresh operation signal and the plurality of control signals.

19. The device according to claim 1, wherein the row address strobe generator is comprised to have the same number of the banks.

20. A self-refresh method, where refresh modes are classified, into a plurality of modes including a HALF of BANK mode for refreshing a half of one bank and a QUARTER of BANK mode for refreshing a quarter of one bank, depending on extended mode register set codes,
the method comprising the step of performing a partial self-refresh operation to an array region where data is stored, by performing one of the plurality of self-refresh modes depending on the extended mode register set codes.
